(19) United States
(12) Patent Application Publication
(10) Pub. No.: US 2014/0160647 A1
(43) Pub. Date: Jun. 12, 2014

(54) FLAT PANEL DISPLAY

(71) Applicants: HON HAI PRECISION INDUSTRY CO., LTD., New Taipei (TW); HONG FU JIN PRECISION INDUSTRY (ShenZhen) CO, LTD., Shenzhen (CN)

(72) Inventors: PENG ZHANG, Shenzhen (CN); WEI-KUANG LIANG, New Taipei (TW)

(73) Assignees: HON HAI PRECISION INDUSTRY CO., LTD., New Taipei (TW); HONG FU JIN PRECISION INDUSTRY (ShenZhen) CO, LTD., Shenzhen (CN)

(21) Appl. No.: 14/010,773

(22) Filed: Aug. 27, 2013

(30) Foreign Application Priority Data
Dec. 6, 2012 (CN) 2012105181396

(51) Int. Cl. H05K 7/12

(52) U.S. Cl. CPC H05K 7/12
USPC 361/679.01

(57) ABSTRACT

A flat panel display which does not utilize adhesive for any attachment includes a front panel, a rear panel, a screen module, and a first mounting piece and a second mounting piece. The screen module is substantially rectangular and all alignments and fastenings are achieved by virtue of the mounting pieces. The first mounting piece includes a first supporting board, a first retaining flange, a first blocking flange, and a first fixing tab. The second mounting piece includes a second supporting board, a second retaining flange, a second blocking flange, and a second fixing tab. The first retaining flange and the first blocking flange are located on two adjacent edges of the first supporting board. The second retaining flange and the second blocking flange are located on two adjacent edges of the second supporting board.

### BACKGROUND

1. Technical Field

The disclosure generally relates to electronic visual displays, especially to a flat panel display.

2. Description of Related Art

Flat panel displays are lighter and thinner than traditional television sets and video displays that use cathode ray tubes. Flat panel displays can be less than 10 centimeters thick, and include a front panel, a screen module (such as liquid crystal board), and a rear panel. The screen module is directly stuck to the front panel and the rear panel with adhesive. However, it is inconvenient to disassemble the screen module when the screen module needs maintenance. Therefore, there is room for improvement within the art.

### BRIEF DESCRIPTION OF THE DRAWINGS

Many aspects of the embodiments can be better understood with reference to the following drawings. The components in the drawings are not necessarily drawn to scale, the emphasis instead being placed upon clearly illustrating the principles of the embodiments. Moreover, in the drawings, like reference numerals designate corresponding parts throughout the several views.

FIG. 1 is an isometric, exploded view of a flat panel display in one embodiment.

FIG. 2 is similar to FIG. 1, but shown from another aspect.

FIG. 3 is an enlarged view of a first mounting piece of the flat panel display of FIG. 1.

FIG. 4 is an enlarged view of a second mounting piece of the flat panel display of FIG. 1.

FIG. 5 is a partial assembled view of the flat panel display of FIG. 1.

FIG. 6 is an assembled view of the flat panel display of FIG. 1.

### DETAILED DESCRIPTION

The disclosure is illustrated by way of example and not by way of limitation in the figures of the accompanying drawings in which like references indicate similar elements. It should be noted that references to “an” or “one” embodiment in this disclosure are not necessarily to the same embodiment, and such references mean “at least one.”

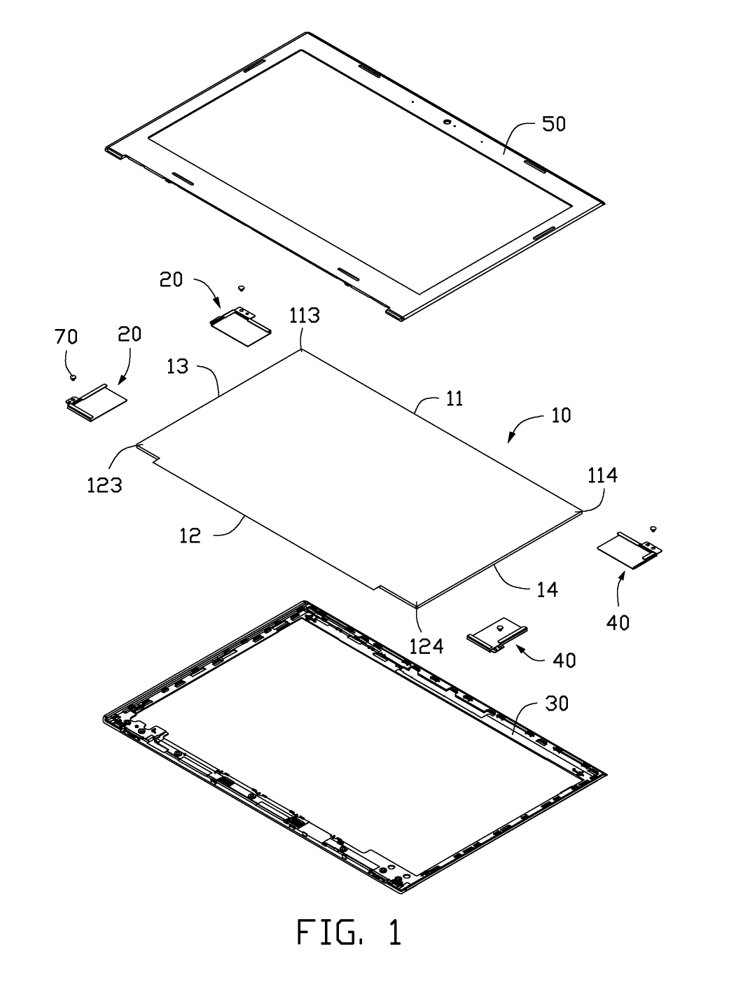

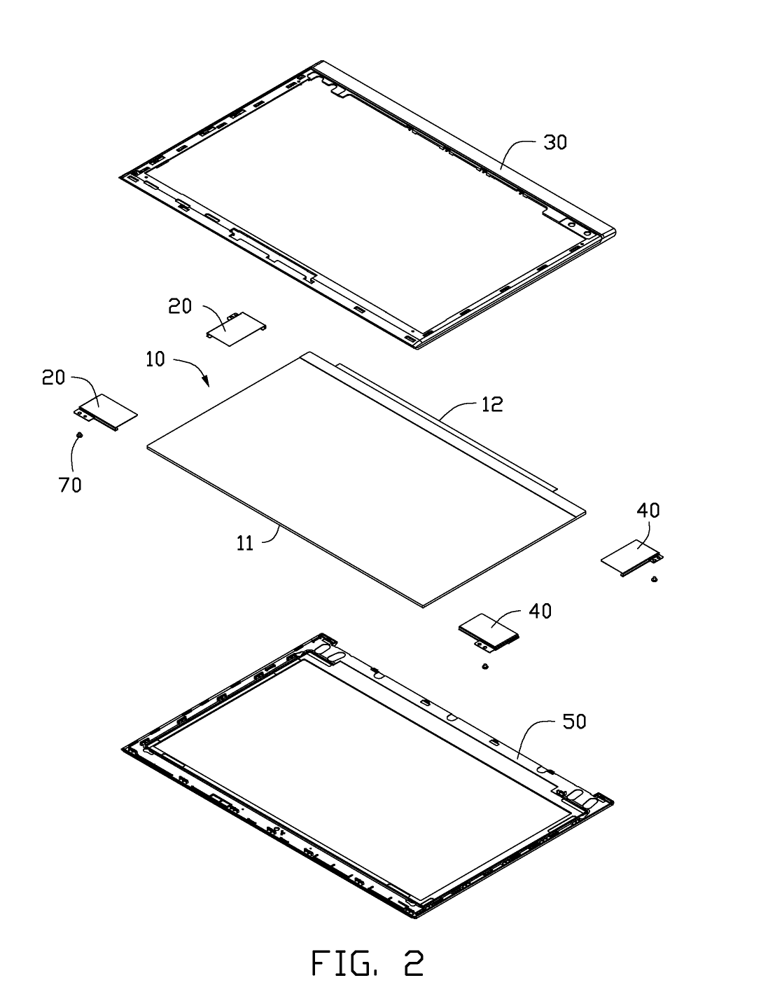

FIG. 1 and FIG. 2 illustrate one embodiment of a flat panel display from different aspects. The flat panel display may be a liquid crystal display. A flat panel display may be used in laptops, mobile phones, digital cameras, and pocket video cameras. The flat panel display includes a screen module 10, a front panel 50, a rear panel 30, and four mounting pieces.

The front panel 50 is a rectangular frame. The screen module 10 is a core display unit and is substantially a rectangular sheet. The screen module 10 can be fixed between the front panel 50 and the rear panel 30 by the four mounting pieces. The screen module 10 includes a top edge 11, a bottom edge 12, a first side edge 13, and a second side edge 14. The top edge 11 is substantially parallel to the bottom edge 12, and is substantially perpendicular to the first side edge 13 and the second side edge 14. The screen module 10 includes a first corner 114, a second corner 124, a third corner 123, and a fourth corner 113. The first corner 114 is adjacent to the second corner 124 and the fourth corner 113, and is diagonally across the third corner 123.

The four mounting pieces include two first mounting pieces 20 and two second mounting pieces 40.

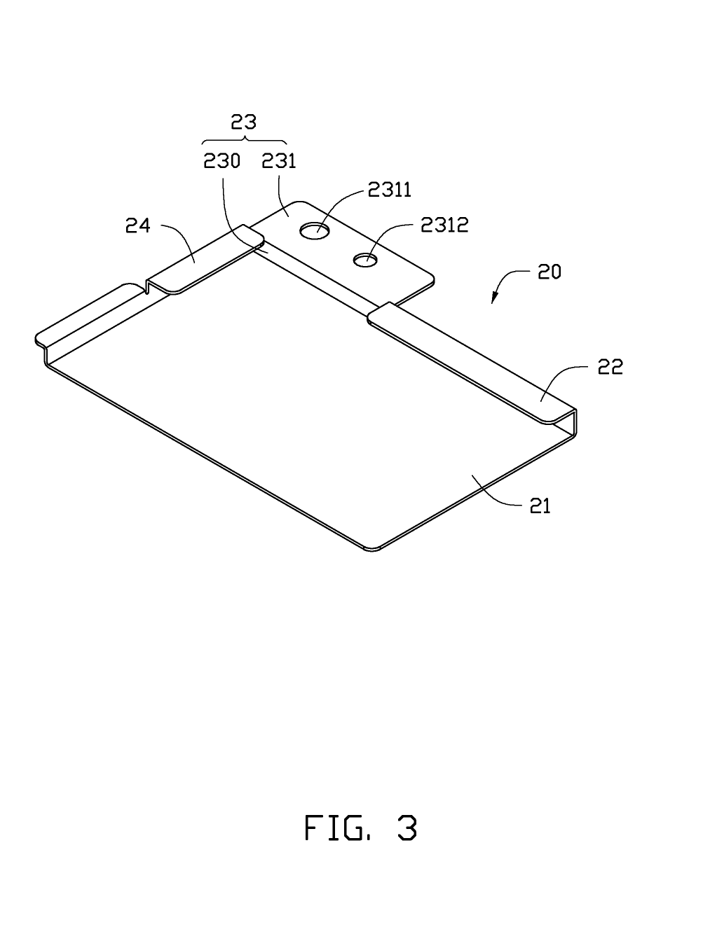

FIG. 3 illustrates an enlarged view of one of first mounting pieces 20. The first mounting pieces 20 include a supporting board 21, a blocking flange 22, a retaining flange 24, and a fixing portion 23. The supporting board 21 is substantially rectangular. A cross section of the block flange 22 is substantially L-shaped, and a cross section of the retaining flange 24 is also substantially L-shaped. A first retaining space is defined between the supporting board 21 with blocking flange 22 and the retaining flange 24. The fixing portion 23 includes an extending rim 230 and a fixing tab 231. The extending rim 230 is substantially perpendicular to the supporting board 21. The fixing tab 231 is substantially perpendicular to the extending rim 230 and is substantially parallel to the supporting board 21. The fixing tab 230 extends away from the supporting board 21. The blocking flange 22 and the fixing portion 23 are located on a top edge of the supporting board 21. The retaining flange 24 is located on a side edge of the supporting board 24. The side edge is adjacent to the top edge. The blocking flange 22 and the retaining flange 24 are located on opposite sides of the fixing portion 23. A first fixing hole 2311 and a second fixing hole 2312 are defined in the fixing tab 231.

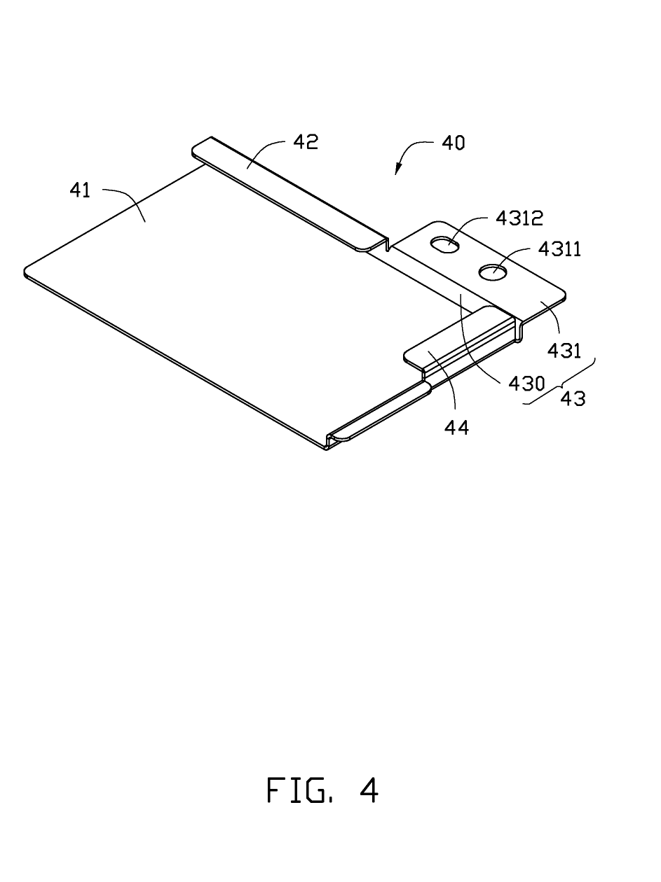

FIG. 4 illustrates an enlarged view of one of second mounting pieces 40. While each second mounting piece 40 is a mirror image of each mounting piece 20, each mounting piece 20 has chirality. The second mounting pieces 40 include a supporting board 41, a blocking flange 42, a retaining flange 44, and a fixing portion 43. The supporting board 41 is substantially rectangular. A cross section of the block flange 42 is substantially L-shaped, and a cross section of the retaining flange 44 is substantially L-shaped. A second retaining space is defined between the supporting board 41 and the blocking flange 42 and the retaining flange 44. The fixing portion 43 includes an extending rim 430 and a fixing tab 431. The extending rim 430 is substantially perpendicular to the supporting board 41. The fixing tab 431 is substantially perpendicular to the extending rim 430 and is substantially parallel to the supporting board 41. The fixing tab 430 extends away from the supporting board 41. The blocking flange 42 and the fixing portion 43 are located on a top edge of the supporting board 41. The retaining flange 44 is located on a side edge of the supporting board 44. The side edge is adjacent to the top edge. The blocking flange 42 and the retaining flange 24 are located on opposite sides of the fixing portion 43. A first fixing hole 4311 and a second fixing hole 4312 are defined in the fixing tab 431.

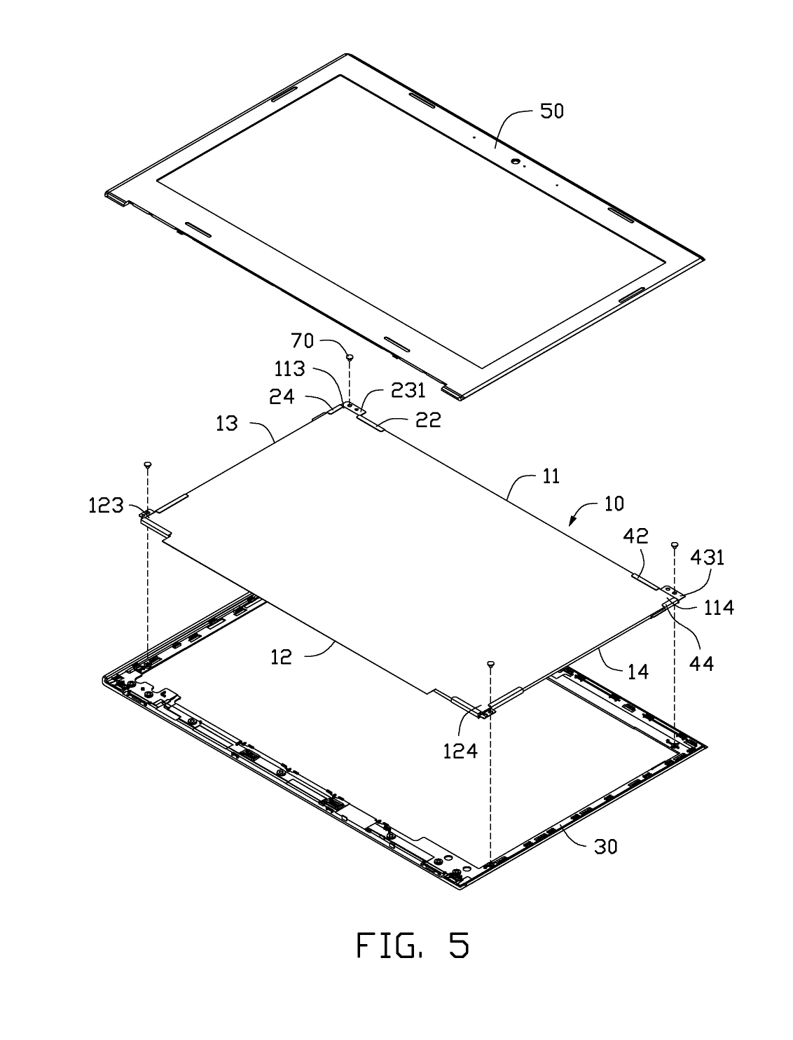

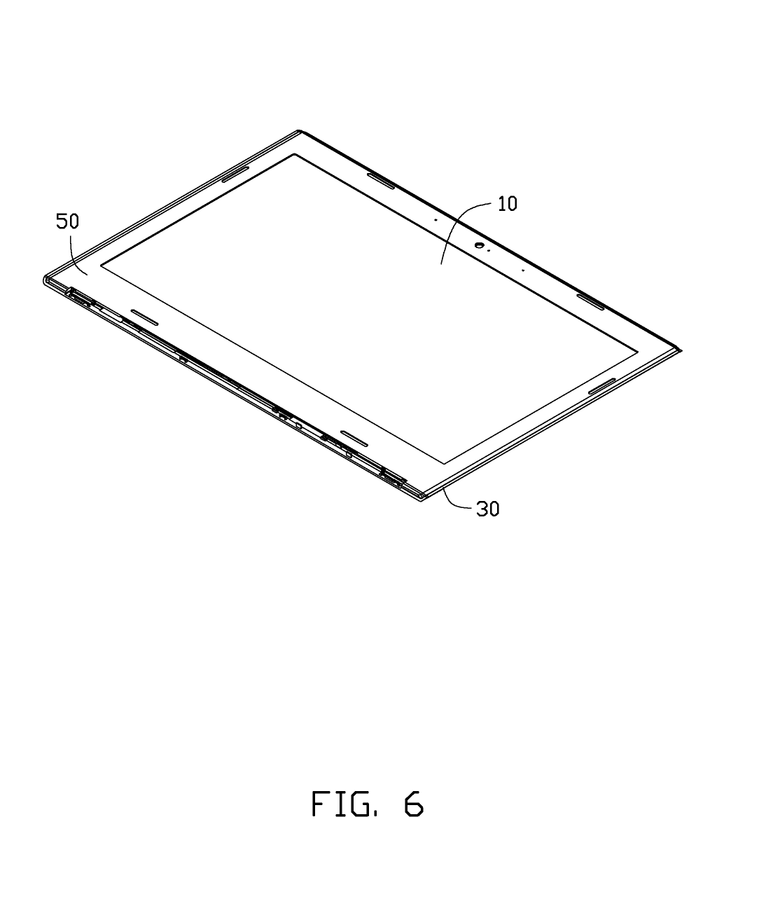

FIG. 5 and FIG. 6 illustrate two assembled views of the flat panel display. In assembly, the four mounting pieces are located on four corners of the screen module 10. The two first mounting pieces 20 are located at the third corner 123 and the fourth corner 113. The two second mounting pieces 40 are located on the first corner 114 and the second corner 124. The retaining flange 24 of the first mounting piece 20 located at the fourth corner 113 and the blocking flange 22 of the first mounting piece 20 located at the third corner 123 grips and limits the first side edge 13 of the screen module 10. The retaining flange 44 of the second mounting piece 40 located at the first corner 114 and the blocking flange 42 of the second mounting piece 40 located at the second corner 124 grip and limit the second side edge 14 of the screen module 10. The blocking flange 22 of the first mounting piece 20 located at the fourth corner 113 and the blocking flange 42 of the second mounting piece 40 located at the first corner 114 grip and limit the top edge 11 of the screen module 10. The retaining flange 24 of the first mounting piece 20 located at the third corner 123 and the retaining flange 44 of the second mounting piece 40 located at the second corner 124 grip and limit the bottom edge 14 of the screen module 10.

The fixing tab 231 of the first mounting piece 20 which is located at the fourth corner 113 and the fixing tab 431 of the second mounting piece 40 which is located at the first corner 114 extend toward a first direction. The fixing tab 231 of the first mounting piece 20 located at the third corner 123 extends toward a second direction. The fixing tab 431 of the second mounting piece 40 located at the second corner 124 extends toward a third direction. The second direction is substantially opposite to the third direction. The first direction is substantially perpendicular to the second direction and the third direction. Each fixing tab 231 and each fixing tab 431 is fixed to the rear panel 30 through a plurality of fasteners 70. The front panel 50 is mounted to the rear panel 30. The flat panel display is thus assembled.

It is to be understood, however, that even though numerous characteristics and advantages have been set forth in the foregoing description of embodiments, together with details of the structures and functions of the embodiments, the disclosure is illustrative only and changes may be made in detail, especially in the matters of shape, size, and arrangement of parts within the principles of the disclosure to the full extent indicated by the broad general meaning of the terms in which the appended claims are expressed.

What is claimed is:

1. A flat panel display, comprising:
a front panel;
a rear panel;
a screen module being substantially rectangular;
a first mounting piece and a second mounting piece, the first mounting piece comprising a first supporting board, a first retaining flange, a first blocking flange, and a first fixing tab; the second mounting pieces comprising a second supporting board, a second retaining flange, a second blocking flange, and a second fixing tab; the first retaining flange and the first blocking flange are located on two adjacent edges of the first supporting board; the second retaining flange and the second blocking flange are located on two adjacent edges of the second supporting board;
wherein the first mounting piece and the second mounting piece are located at two opposite corners of the screen module, the first retaining flange blocks the screen module from moving along a first direction, the second blocking flange blocks the screen module from moving along a second direction opposite to the first direction; the first block flange blocks the screen module from moving along a third direction, the second retaining flange blocks the screen module from moving along a fourth direction opposite to the third direction; the first direction is substantially perpendicular to the second direction; and the first fixing tab and the second fixing tab are fixed to the rear panel, and the front panel is mounted to the rear panel.

2. The flat panel display of claim 1, wherein the first mounting piece and the second mounting piece are substantially mirrored.

3. The flat panel display of claim 1, wherein a cross section of the first retaining flange is substantially L-shaped.

4. The flat panel display of claim 1, wherein a cross section of the first block flange is substantially L-shaped.

5. The flat panel display of claim 1, wherein the first fixing tab and the second fixing tab are substantially parallel to the screen module.

6. The flat panel display of claim 1, wherein the first supporting board and the second supporting board are substantially rectangular.

7. The flat panel display of claim 1, wherein the first blocking flange and the first fixing tab are located on a first top edge of the supporting board, the first retaining flange is located on a first side edge of the first supporting board, the first top edge is substantially perpendicular to the first side edge; the second blocking flange and the second fixing tab are located on a second top edge of the supporting board, the second retaining flange is located on a second side edge of the second supporting board, and the second top edge is substantially perpendicular to the second side edge.

8. The flat panel display of claim 7, wherein the first blocking flange and the second retaining flange are located on opposite sides of the first fixing tab; and the second blocking flange and the second retaining flange are located on opposite sides of the second fixing tab.

9. The flat panel display of claim 1, wherein at least one of the first retaining flange and the first blocking flange is configured to prevent the screen module from moving away from the first supporting board; at least one of the second retaining flange and the second blocking flange is configured to prevent the screen module from moving away from the second supporting board.

10. The flat panel display of claim 1, wherein an extending direction of the first fixing tab is substantially perpendicular to an extending direction of the second fixing tab.

11. A flat panel display, comprising:
a front panel;
a rear panel;
a screen module being substantially rectangular;
two first mounting pieces and two second mounting pieces, each of the two first mounting pieces comprising a first supporting board, a first retaining flange, a first blocking flange, and a first fixing tab; each of the two second mounting pieces comprising a second supporting board, a second retaining flange, a second blocking flange, and a second fixing tab; the first retaining flange and the first blocking flange are located on two adjacent edges of the first supporting board; the second retaining flange and the second blocking flange are located on two adjacent edges of the second supporting board;
wherein the two first mounting pieces are located at two adjacent corners of the screen module, the two second mounting pieces are located at the other two adjacent corners of the screen module, the first fixing tab and the second fixing tab are fixed to the rear panel, and the front panel is mounted to the rear panel, and the two first mounting pieces and the two second mounting pieces fixes the screen module to the rear board.

12. The flat panel display of claim 11, wherein the first mounting piece and the second mounting piece are substantially mirrored.

13. The flat panel display of claim 11, wherein a cross section of the first retaining flange is substantially L-shaped.

14. The flat panel display of claim 11, wherein a cross section of the first block flange is substantially L-shaped.

15. The flat panel display of claim 11, wherein the first fixing tab and the second fixing tab are substantially parallel to the screen module.

16. The flat panel display of claim 11, wherein the first supporting board and the second supporting board are substantially rectangular.

17. The flat panel display of claim 11, wherein the first blocking flange and the first fixing tab are located on a first top edge of the supporting board, the first retaining flange is located on a first side edge of the first supporting board, the first top edge is substantially perpendicular to the first side edge; the second blocking flange and the second fixing tab are located on a second top edge of the supporting board, the second retaining flange is located on a second side edge of the second supporting board, and the second top edge is substantially perpendicular to the second side edge.

18. The flat panel display of claim 17, wherein the first blocking flange and the second retaining flange are located on opposite sides of the first fixing tab; and the second blocking flange and the second retaining flange are located on opposite sides of the second fixing tab.

19. The flat panel display of claim 11, wherein at least one of the first retaining flange and the first blocking flange is configured to prevent the screen module from moving away from the first supporting board; at least one of the second retaining flange and the second blocking flange is configured to prevent the screen module from moving away from the second supporting board.

20. The flat panel display of claim 11, wherein an extending direction of the first fixing tab is substantially perpendicular to an extending direction of the second fixing tab.
